(19) United States
(12) Patent Application Publication
(10) Pub. No.: US 2016/0200599 A1
(43) Pub. Date: Jul. 14, 2016

(54) FLEXIBLE COMPOSITE ELECTRODE FOR DESALTING, METHOD FOR MANUFACTURING SAME, AND DESALTING DEVICE USING SAME

(71) Applicant: AMOGREENTECH CO., LTD., Gimpo-si (KR)

(72) Inventors: In Yong SEO, Seoul (KR); Jun Sik HWANG, Incheon (KR)

(21) Appl. No.: 15/074,107

(22) Filed: Mar. 18, 2016

Related U.S. Application Data
(63) Continuation-in-part of application No. PCT/KR2014/009478, filed on Oct. 8, 2014.

(30) Foreign Application Priority Data
Oct. 8, 2013 (KR) 10-2013-0119981

(51) Int. Cl. C02F 1/469; B29C 47/00; C23C 14/20; D01D 5/00; C02F 1/46; C23C 16/06

(52) U.S. Cl. CPC C02F 1/4691; C02F 1/4604; C23C 16/06; C23C 14/20; D01D 5/003; B29C 47/0076; C02F 2101/20

(57) ABSTRACT

Provided are a deionization flexible composite electrode, a method of manufacturing the deionization flexible composite electrode, and a deionization apparatus using the same. The deionization flexible composite electrode includes: a porous substrate having fine pores; and a conductive film portion that is formed on one surface or both surfaces of the porous substrate. The method of manufacturing a deionization flexible composite electrode comprises: preparing a porous substrate having fine pores; and depositing a conductive material in the porous substrate to thus form a conductive film portion on one surface or both surfaces of the porous substrate.

### TECHNICAL FIELD

The present invention relates to a deionization flexible composite electrode, and more specifically, to a deionization flexible composite electrode having a very high specific surface area, enabling fabrication of an ultra-thin film and slimming thereof, and having excellent flexibility, without the need for a separate current collector, by implementing an electrode structure in which a conductive material is penetrated into fine pores of a porous substrate, a method of manufacturing the deionization flexible composite electrode, and a deionization apparatus using the same.

### BACKGROUND ART

In general, only 0.0086% of all the earth's water volume may be used. When considering disasters due to climate change in mind, water may not be available enough.

Water is very important to human life and is used variously as water for living or industrial water. Water may be contaminated with heavy metals, nitrate, fluoride, etc., due to industrial development and it is very harmful to health to drink contaminated water.

Recently, deionization technologies for purifying contaminated water and sea water for use as agricultural, industrial, or irrigation water have been variously studied.

These deionization technologies are techniques for deionization or desalination of water by removing various suspended solids or ion components contained in the sea water or polluted water such as waste water, and may employ an evaporation method to evaporate water by using a heat source such as fossil fuels or electric power, a filtration method to filter and remove foreign materials by using a separation membrane, or an electrodialysis method to remove ions by using an electrolytic action of an electrode cell.

The evaporation method evaporates moisture by using fossil fuels or electricity as a heat source, is inefficient due to the large volume of the deionization equipment, increases the manufacturing cost due to an increase in the consumption of energy, and causes contamination of air due to the use of fossil fuels.

The filtration method removes foreign matters by applying a high pressure to a separator and thus the cost of energy increases.

The electrodialysis method has to constantly replace an electrode cell with another, and does not only generate a waste factor due to the replacement of the electrode cell but also has the disadvantage of increasing human and material incidental expenses in accordance with the replacement of the electrode cell.

Korean Patent Registration Publication No. 501417 discloses a waste water deionization apparatus using a reverse osmosis membrane method/electrode method, the waste water deionization apparatus comprising: a reverse osmosis membrane device to primarily remove salt components from water to be treated in which the water to be treated is introduced with a predetermined pressure into the reverse osmosis membrane device; a deionization electrode device that secondarily removes salt components from the water that has been primarily processed in the reverse osmosis membrane device in which a spacer, a positive electrode and a negative electrode are sequentially provided in a cylindrical tank; an energy recovery device for utilizing a brine-side pressure of the reverse osmosis membrane device for use to pressurize inlet water of the deionization electrode device; a power supply device for supplying power to the positive electrode and the negative electrode provided in the deionization electrode device; and a controller for controlling valves provided in pipes through which the water to be process in order to perform a deionization process for deionizing the water to be treated in which the water to be treated is introduced into the deionization electrode device, and a reproduction process for desorbing ions adsorbed to the electrode during the deionization process. However, such a waste water deionization apparatus includes the reverse osmosis membrane device and the deionization electrode device individually and thus may cause the large size of the deionization apparatus and require a lot of manufacturing cost.

Thus, the present inventors have constantly proceeded a study on a technique of slimming a deionization apparatus and reducing a production cost, to thus invent and derive structural features of a current collector module capable of implementing an ultra-thin film type current collector simultaneously having a high capacitance, to thereby have completed the present invention that is more economical, and possibly utilizable, and competitive.

### SUMMARY OF THE INVENTION

To solve the above problems or defects, it is an object of the present invention to provide a deionization flexible composite electrode capable of reducing a manufacturing cost, having a high storage capacity, and obtaining a very high specific surface area, by employing a current collector that is formed by penetrating a conductive material into fine pores of a porous substrate as a current collector, a method of manufacturing the deionization flexible composite electrode, and a deionization apparatus using the same.

It is another object of the present invention to provide a deionization flexible composite electrode, a method of manufacturing the same, and a deionization apparatus using the same, in which an electrode and a current collector are integrated to then be ultra-thinned to thereby slim the deionization apparatus.

It is still another object of the present invention to provide a deionization flexible composite electrode, a method of manufacturing the same, and a deionization apparatus using the same that can implement a flexible deionization module.

The objects of the present invention are not limited to the above-described objects, and other objects and advantages of the present invention can be appreciated by the following description and will be understood more clearly by embodiments of the present invention.

To accomplish the above and other objects of the present invention, according to an aspect of the present invention, there is provided a deionization flexible composite electrode comprising: a porous substrate having fine pores; and a conductive film portion that is formed on one surface or both surfaces of the porous substrate.

In addition, according to another aspect of the present invention, there is provided a method of manufacturing a deionization flexible composite electrode, the method comprising the steps of: preparing a porous substrate having fine pores; and depositing a conductive material in the porous substrate to thus form a conductive film portion on one surface or both surfaces of the porous substrate.

Furthermore, according to still another aspect of the present invention, there is provided a deionization apparatus comprising: a first deionization flexible composite electrode including a first conductive film portion that is formed on one surface or both surfaces of a first porous substrate having fine pores; and a second deionization flexible composite electrode including a second conductive film portion that is formed on one surface or both surfaces of a second porous substrate having fine pores in which the second deionization flexible composite electrode is disposed to be spaced from and face the first deionization flexible composite electrode.

As described above, a deionization flexible composite electrode according to the present invention is implemented to have an electrode structure in which a conductive material is penetrated into fine pores of a porous substrate, to thereby provide an effect capable of manufacturing an electrode having a very high specific surface area and an ultra-thin film.

In addition, the present invention has an advantage capable of implementing a deionization flexible composite electrode by employing a nanofiber web or nonwoven fabric having an excellent flexibility as an electrode support.

In addition, the present invention provides a technology capable of producing a deionization flexible composite electrode, which may easily control pore size of an electrode support and implement an electrode having pores of uniform size, to thereby improve efficiency of adsorption and desorption of ions, and which does not use a binder to thus avoid the binder from being dissolved and eluted and can reduce a production cost with a simple production process.

In addition, the present invention has an advantage capable of implementing a deionization flexible composite electrode by manufacturing an electrode by penetrating a conductive material into fine pores of a porous substrate, to thus reduce a production cost and have a high storage capacity at a lower cost.

In addition, the present invention may implement an ultra-thin film type deionization apparatus by implementing a deionization flexible composite electrode in which a conductive film is formed on a porous substrate having fine pores.

### DESCRIPTION OF DRAWINGS

FIG. 1 is a schematic cross-sectional view illustrating a deionization flexible composite electrode according to a first embodiment of the present invention.

FIG. 2 is a conceptual view for explaining that a deposition material is penetrated into fine pores of a porous substrate that is applied to the first embodiment of the present invention.

FIG. 3 is a schematic cross-sectional view illustrating a deionization flexible composite electrode according to a second embodiment of the present invention.

FIGS. 4A and 4B are schematic cross-sectional views illustrating a method of manufacturing a deionization flexible composite electrode in accordance with the first embodiment of the present invention.

FIG. 5 is a conceptual view for explaining a deionization apparatus according to the first embodiment of the present invention.

FIG. 6 is a conceptual view for explaining a deionization apparatus according to the second embodiment of the present invention.

FIG. 7 is a conceptual view for explaining a deionization apparatus according to a third second embodiment of the present invention.

FIG. 8 is a conceptual diagram for explaining a structure that filter modules of FIG. 7 are stacked.

### DETAILED DESCRIPTION OF THE INVENTION

Hereinafter, embodiments of the present invention will be described in detail with reference to the accompanying drawings. In the process, the size and shape of the components illustrated in the drawings may be exaggerated for convenience and clarity of explanation. Further, by considering the configuration and operation of the present invention, the specifically defined terms can be changed according to user's or operator's intention, or the custom. Definitions of these terms herein need to be made based on the contents across the whole application.

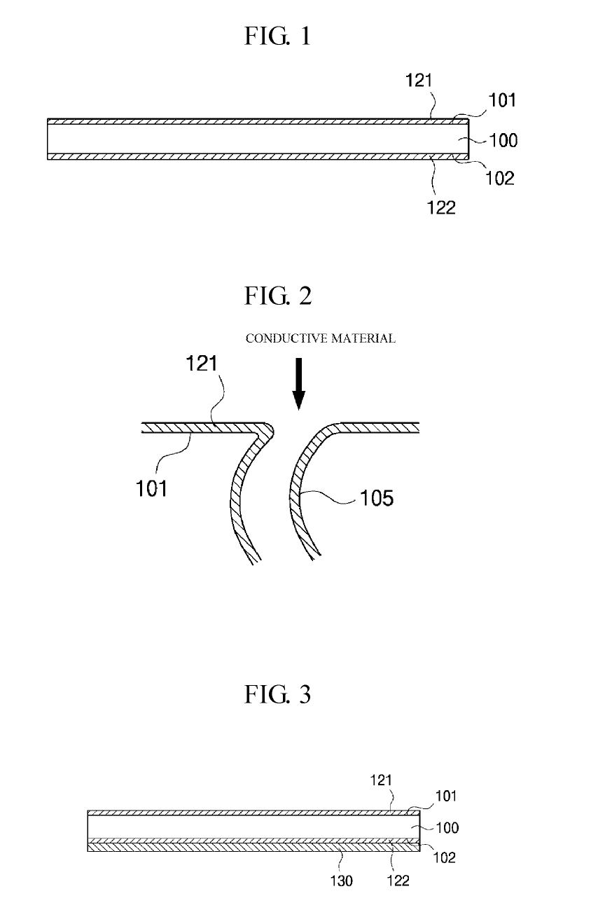

FIG. 1 is a schematic cross-sectional view illustrating a deionization flexible composite electrode according to a first embodiment of the present invention. FIG. 2 is a conceptual view for explaining that a deposition material is penetrated into fine pores of a porous substrate that is applied to the first embodiment of the present invention. FIG. 3 is a schematic cross-sectional view illustrating a deionization flexible composite electrode according to a second embodiment of the present invention.

Referring to FIG. 1, a deionization flexible composite electrode according to a first embodiment of the present invention includes: a porous substrate 100 having fine pores; and a conductive film 121 or 122 that is formed on one surface 101 or 102 of the porous substrate 100. Alternatively, conductive films 121 and 122 may be formed on both surfaces 101 and 102 of the porous substrate 100, other than the conductive film 121 or 122 that is formed on one surface 101 or 102 of the porous substrate 100.

Here, the conductive film 121 or 122 may be formed by depositing a conductive material on one surface 101 or 102 of the porous substrate 100. Otherwise, the conductive films 121 and 122 may be formed by depositing a conductive material on both surfaces 101 and 102 of the porous substrate 100. Here, the conductive material may be at least one metal such as nickel (Ni), copper (Cu), stainless steel (SUS), titanium (Ti), chromium (Cr), manganese (Mn), iron (Fe), cobalt (Co), zinc (Zn), molybdenum (Mo), tungsten (W), silver (Ag), gold (Au), and aluminum (Al). Preferably, a deposition film may be formed by depositing copper. Here, the conductive material may be deposited on the whole surface of the porous substrate 100 including one surface 101 and the other surface 102 of the porous substrate 100.

The porous substrate 100 may employ a lamination structure of laminating a nanofiber web on one surface or both surfaces of a nonwoven fabric in which the nanofiber web is formed by laminating nanofibers obtained by electrospinning a polymer material and include three-dimensional fine pores. The lamination structure of the nanofiber web and the nonwoven fabric may be a structure that the nanofiber web is laminated on one surface of the nonwoven fabric, or a structure that the nanofiber web is laminated on both surfaces of the nonwoven fabric. Here, when a deionization flexible composite electrode is implemented by employing the lamination structure of laminating the nanofiber web on one surface or both surfaces of the nonwoven fabric, a flexible electrode having a high specific surface area may be produced.

That is, the porous substrate 100 may be applied as the lamination structure of the nanofiber web and the nonwoven fabric, or the lamination structure of the nanofiber web/the nonwoven fabric/the nanofiber web. In this case, thickness of the nanofiber web is preferably thinner than that of the nonwoven fabric.

Thus, when the deionization flexible composite electrode is formed by employing the lamination structure of the nanofiber web and the nonwoven fabric, the nonwoven fabric is more inexpensive than the nanofiber web, and the former has the higher strength than the latter, to thereby reduce the production cost of the deionization flexible composite electrode and simultaneously improve the strength. In addition, since the nonwoven fabric also includes a large number of pores, a conductive material for deposition may be penetrated into the nonwoven fabric.

The porous substrate 100 is provided with fine pores. Accordingly, when the conductive material is deposited on the porous substrate 100 having fine pores, the deposited conductive material is penetrated into the fine pores, and thus deposition films are formed inside the fine pores, and the pores of the porous substrate 100 after deposition become finer than those of the porous substrate 100 before deposition.

Therefore, when the conductive films are formed on one surface and the other surface of the porous substrate 100 by a phenomenon that the conductive material to be deposited is penetrated into the fine pores of the porous substrate 100, the conductive films formed on one surface and the other surface of the porous substrate 100 are electrically connected to each other. Therefore, the deionization flexible composite electrode according to the embodiment of the present invention employs an electrode structure having fine pores that are capable of adsorbing ions and thus may be used as a capacitive deionization electrode.

That is, as shown in FIGS. 1 and 2, the conductive material that is deposited into one surface 101 of the porous substrate 100 is penetrated into the fine pore 105 of the porous substrate 100, and likewise, the conductive material that is deposited into the other surface 102 of the porous substrate 100 is penetrated into the fine pore 105 of the porous substrate 100. The conductive films 121 and 122 formed on one surface and the other surface of the porous substrate 100 are electrically connected to each other by the conductive material penetrated into the fine pore 105 of the porous substrate 100.

Referring to FIG. 3, a deionization flexible composite electrode according to a second embodiment of the present invention is the same as that of the first embodiment thereof, in that a conductive film 121 or 122 may be formed on one surface 101 or 102 of the porous substrate 100, and alternatively, conductive films 121 and 122 may be formed on both surfaces 101 and 102 of the porous substrate 100. However, the deionization flexible composite electrode according to a second embodiment of the present invention further includes a coat layer 130 coated on the conductive film 122 formed on the porous substrate 100.

The coat layer 130 plays a role of improving the electrical conductivity of the deionization flexible composite electrode, and does not require a separate current collector. Accordingly, the deionization flexible composite electrode may be ultra-thinned and slimmed, to thereby reduce the size of a deionization apparatus.

Thus, the deionization flexible composite electrode according to the first embodiment of the present invention is implemented as an electrode structure in which the conductive material is penetrated into the fine pores of the porous substrate such as the nanofiber web, and has the advantage of producing an electrode of a very high specific surface area, and an ultra-thin film electrode having a thickness of 1 μm to 50 μm.

In addition, the present invention has an advantage capable of implementing a deionization flexible composite electrode by employing a nanofiber web or nonwoven fabric having an excellent flexibility as an electrode support, and mounting the deionization flexible composite electrode even on a deionization apparatus of a curved intrinsic shape.

Further, the present invention provides an electrode which may easily control pore size and have pores of uniform size, to thereby improve efficiency of adsorption and desorption of ions.

Moreover, the present invention provides an electrode which does not use a binder to thus avoid the binder from being dissolved and eluted and can reduce a production cost with a simple production process.

In addition, the present invention has an advantage capable of implementing a deionization flexible composite electrode by manufacturing an electrode by penetrating a conductive material into fine pores of a porous substrate, to thus reduce a production cost and have a high storage capacity at a lower cost.

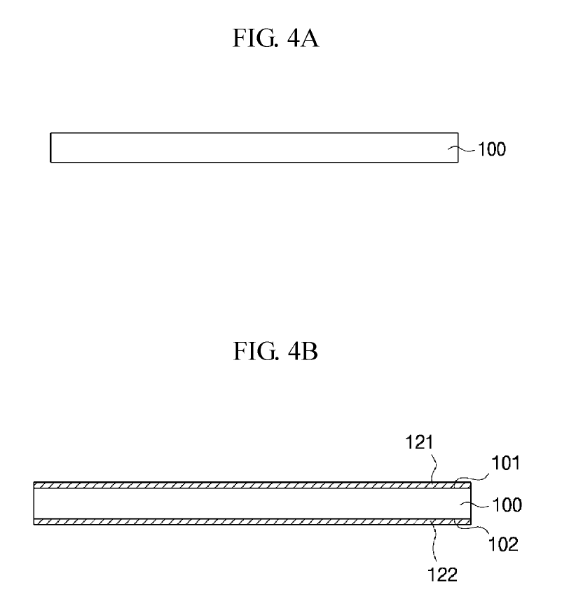

FIGS. 4A and 4B are schematic cross-sectional views illustrating a method of manufacturing a deionization flexible composite electrode in accordance with the first embodiment of the present invention.

Referring to FIGS. 4A and 4B, the method of manufacturing a deionization flexible composite in accordance with the embodiment of the present invention includes preparing a porous substrate 100 of a lamination structure of a nanofiber web having three-dimensional fine pores in which nanofibers that are formed by electrospinning a polymer material are laminated and the nanofiber web is laminated on one surface or both surface of a nonwoven fabric (FIG. 4A).

The porous nanofiber web can be obtained by electrospinning a mixed spinning solution that is formed by dissolving a single kind of a polymer or a mixture of at least two kinds of polymers in a solvent, or can be obtained by dissolving respectively different polymers in a solvent and then cross-spinning the electrospun spinning solution through respectively different spinning nozzles.

When forming a mixed spinning solution by using two types of polymers, for example, in the case of mixing polyacrylonitrile (PAN) as a heat-resistant polymer and polyvinylidene fluoride (PVDF) as an adhesive polymer (or a water-swellable polymer), it is preferable to mix both in a range of 8:2 to 5:5 at a weight ratio.

In the case that a mixing ratio of the heat-resistant polymer and the adhesive polymer is less than 5:5 at a weight ratio, heat resistance performance of the mixed spinning solution falls to thus fail to exhibit required high temperature properties. On the contrary, in the case that a mixing ratio of the heat-resistant polymer and the adhesive polymer is larger than 8:2 at a weight ratio, the intensity of the mixed spinning solution falls to thereby cause a spinning trouble to occur.

When preparing a spinning solution by using a mixed polymer of a heat-resistant polymer material and a swellable polymer material in some embodiments of the present invention, a single solvent or a two-component mixed solvent that is formed by mixing a high boiling point solvent and a low boiling point solvent may be employed. In this case, a mixing ratio of the two-component mixed solvent and the entire polymer material is preferably set to a weight ratio of about 8:2.

In some embodiments of the present invention, considering that the solvent volatilization may not be well achieved depending on the type of the polymer when using a single solvent, it may be designed to pass through a pre-air dry zone by a pre-heater after a spinning process, and undergo a process of adjusting the amount of the solvent and moisture remaining on the surface of the porous nanofiber web, as will be described later.

Any polymers may be used in the case of fiber forming polymers that may be dissolved in a solvent to thus form a spinning solution, and then may be spun in an electrospinning method to thus form nanofibers.

The heat-resistant polymer resin that may be used in the present invention is a resin that may be dissolved in an organic solvent for electrospinning and whose melting point is 180° C. or higher, for example, any one selected from the group consisting of: aromatic polyester such as polyacrylonitrile (PAN), polyamide, polyimide, polyamide-imide, poly meta-phenylene iso-phthalamide, polysulfone, polyether ketone, polyethylene terephthalate, polytrimethylene terephthalate, and polyethylene naphthalate; polyphosphazenes such as polytetrafluoroethylene, polydiphenoxy phosphazene, and poly {bis [2-(2-methoxyethoxy)phosphazene]}; polyurethane copolymer containing at least one of polyurethane and polyether urethane; cellulose acetate; cellulose acetate butylrate; and cellulose acetate propionate.

The swellable polymer material that may be used in the present invention is a resin that is swollen in an electrolyte, and may be formed into an ultrafine fiber by an electrospinning method, for example, any one selected from the group consisting of: polyvinylidene fluoride (PVDF), poly (vinylidene fluoride-co-hexafluoropropylene), perfluoropolymer, polyvinyl chloride or polyvinylidene chloride, and copolymer thereof; polyethylene glycol derivatives containing at least one of polyethylene glycol dialkylether and polyethylene glycol dialkyl ester; polyoxide containing at least one of poly (oxymethylene-oligo-oxyethylene), polyethylene oxide and polypropylene oxide; polyacrylonitrile copolymer containing at least one of polyvinyl acetate, poly (vinyl pyrrolidone-vinyl acetate), polystyrene, polystyrene acrylonitrile copolymer, and polyacrylonitrile methyl methacrylate copolymer; and polymethyl methacrylate, and polymethyl methacrylate copolymer, and any one combination thereof

The porous nanofiber web is made of ultra-fine nanofibers that are formed by dissolving a single or mixed polymer in a solvent to thus form a spinning solution, and spinning the spinning solution, and then calendered at a temperature below or equal to a melting point of the polymer thereby adjusting sizes of the pores and thickness of the web.

The porous nanofiber web is formed of, for example, nanofibers to have a diameter of 50 to 1500 μm, and are set to 1 to 100 μm thick, preferably set to 10 to 30 μm in thickness. The sizes of the fine pores are set to several tens to several hundreds of micrometers μm, and the porosity is set to 50 to 90%.

In this case, the porous substrate 100 may be formed of a porous nonwoven fabric alone or may be formed by laminating porous nonwoven fabrics, if necessary, in order to reinforce the strength of the porous nanofiber web and the support. The porous nonwoven fabric may employ any one of a nonwoven fabric made of PP/PE fibers of a double structure in which polyethylene (PE) is coated on the outer periphery of polypropylene (PP) fibers, as a core, a polyethylene terephthalate (PET) nonwoven fabric made of PET fibers, and a nonwoven fabric made of cellulose fibers.

Then, in some embodiments, conductive films 121 and 122 may be formed on one surface 101 and the other surface 102 of the porous substrate 100, respectively, by depositing a conductive material (FIG. 4B). The conductive films 121 and 122 may be formed by using a deposition process using a CVD (Chemical Vapor Deposition) method or a PVD (Physical Vapor Deposition) method, depending on a material of the conductive material.

In the present invention, after the process of FIG. 4B, a coating process may be performed on the conductive film 122 formed on the other surface 102 of the porous substrate 100, to thereby further perform a process of forming a coat layer (not shown).

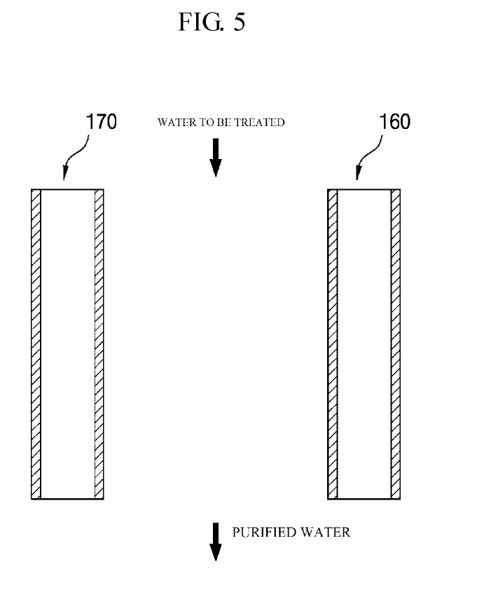

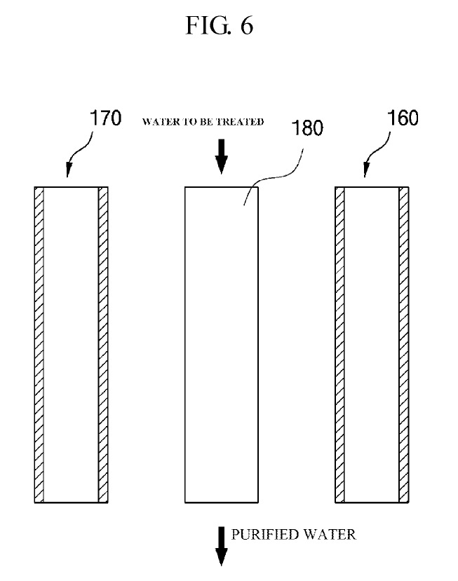

FIG. 5 is a conceptual view for explaining a deionization apparatus according to the first embodiment of the present invention, and FIG. 6 is a conceptual view for explaining a deionization apparatus according to the second embodiment of the present invention.

Referring to FIG. 5, the deionization apparatus according to the first embodiment of the present invention includes: a first deionization flexible composite electrode 160 including a first conductive film portion that is formed on one surface or both surfaces of a first porous substrate having fine pores; and a second deionization flexible composite electrode 170 including a second conductive film portion that is formed on one surface or both surfaces of a second porous substrate having fine pores in which the second deionization flexible composite electrode is disposed to be spaced from and face the first deionization flexible composite electrode.

The first and second deionization flexible composite electrodes 160 and 170 are current collectors having respectively different polarities or potentials. For example, the first deionization flexible composite electrode 160 is a negative pole current collector, and the second deionization flexible composite electrode 170 is a positive pole current collector.

When a potential is applied between the first and second deionization flexible composite electrodes 160 and 170, ions included in water to be treated such as sea water or waste water entering one side of the deionization apparatus are adsorbed on the surfaces of the first and second deionization flexible composite electrodes 160 and 170 and removed from the water to be treated, by electric attraction from an electric double layer formed on the surfaces of the first and second deionization flexible composite electrodes 160 and 170, to thereby discharge purified water through the other side of the deionization apparatus. In this case, by the electric attraction, the porous electrodes adsorb ions contained in the water to be treated such as sea water or waste water.

Referring to FIG. 6, as compared with the deionization apparatus according to the first embodiment, the deionization apparatus according to the second embodiment of the present invention further includes a nonwoven fabric 180 that is positioned in a space between the first and second deionization flexible composite electrodes 160 and 170, and through which water to be treated passes.

The deionization apparatus according to the second embodiment of the present invention adsorbs ions from water to be treated passing through the nonwoven fabric 180 at potentials applied to the first and second deionization flexible composite electrodes, to thereby implement capacitive deionization.

Since a plurality of pores of irregular shapes are formed in the nonwoven fabric 180, the direction of flow of water to be treated passed between the first and second deionization flexible composite electrodes 160 and 170 varies in various patterns, and thus adsorption efficiency of ions may be increased by a potential applied between the first and second deionization flexible composite electrodes 160 and 170.

Therefore, the deionization apparatuses according to the first and second embodiments of the present invention may implement an ultra-thin deionization apparatus by employing an ultra-thin deionization flexible composite electrode by forming a conductive film or conductive films on a porous substrate having fine pores.

A coat layer may be further formed on a conductive film or conductive films applied to the deionization apparatuses according to the first and second embodiments of the present invention, in order to improve electrical conductivity.

Meanwhile, the deionization apparatuses according to the first and second embodiments of the present invention may be backwashed by switching the electrode potential to zero volts (V) or the inverse potential when the adsorbed ions reach the capacitance of the deionization flexible composite electrode, thereby desorbing ions adsorbed in the deionization flexible composite electrode to thus be recycled.

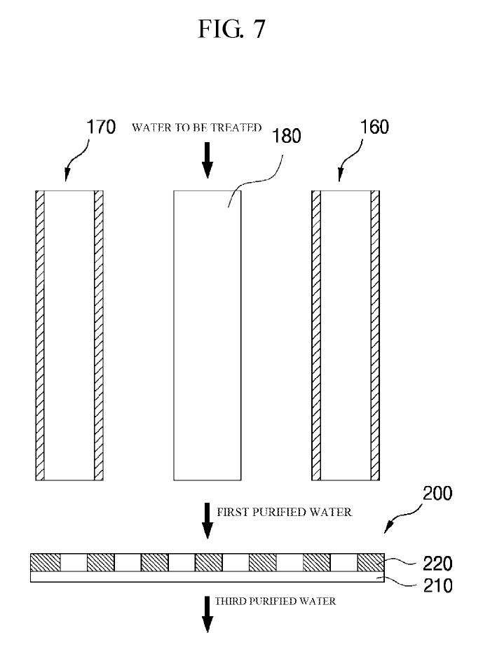

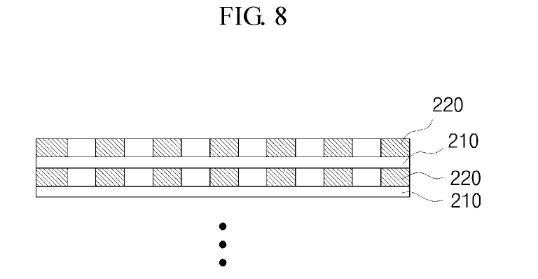

FIG. 7 is a conceptual view for explaining a deionization apparatus according to a third embodiment of the present invention, and FIG. 8 is a conceptual diagram for explaining a structure that filter modules of FIG. 7 are stacked.

Referring to FIG. 7, the deionization apparatus according to the third embodiment of the present invention may further include a filter module 200 to filter out heavy metal ions and bacterial substances on the other end of the deionization apparatus through which purified water is discharged.

The filter module 200 is provided at the other end of the deionization apparatus to eliminate heavy metal ions and bacterial substances such as bacteria and microorganisms. Here, FIG. 7 is a conceptual view, in which the filter module 200 is shown as being spaced from the other end of the deionization apparatus, but is not limited thereto. However, the first and second deionization flexible composite electrodes 160 and 170 should be constructed in a structure for preventing leakage of the first purified water that has passed through between the first and second deionization flexible composite electrodes 160 and 170 by default. For example, the filter module 200 may be in close contact with the other end of the deionization apparatus from which the first purified water is discharged, or a guide for preventing the leakage of the first purified water may be provided between each of the first and second deionization flexible composite electrodes 160 and 170 and the filter module 200.

The filter module 200 includes: a silver (Ag) mesh module 220 for removing heavy metal ions from first purified water that is obtained by removing ions from water to be treated by the first and second deionization flexible composite electrodes 160 and 170; and a nanofiber web 210 that is fixed to the Ag mesh module 220, thereby filtering the bacterial substances from second purified water (not shown) from which the heavy metal ions have been removed.

Since the three-dimensional fine pores are formed in the nanofiber web 210, the bacterial substances are collected by the nanofiber web 210 while the second purified water passes through the nanofiber web 210, to thereby discharge third purified water.

In addition, as shown in FIG. 8 the filter module 200 may be implemented into a repeatedly laminated structure of the mesh module 220 and the nanofiber web 210 in which the mesh module 220 and the nanofiber web 210 are stacked repeatedly.

Thus, in some embodiments of the present invention, the deionization apparatus further includes the filter module, to thereby filter the heavy metal ions and bacterial substances.

Meanwhile, in some embodiments of the present invention, the nanofiber web 210 may be implemented in a nanofiber web in which the nanofibers containing silver nano-materials are laminated. In other words, purified water having passed through the nanofiber web containing silver nano-materials prevents propagation of bacteria to thus increase the antibacterial properties.

Accordingly, a silver nano-material or a polymer material is dissolved in an organic solvent, to thus prepare a spinning solution, and then the spinning solution is electrospun to thus prepare nanofibers. Then, the nanofibers are laminated to thus prepare a nanofiber web.

As described above, the present invention has been described with respect to particularly preferred embodiments. However, the present invention is not limited to the above embodiments, and it is possible for one of ordinary skill in the art to make various modifications and variations, without departing off the spirit of the present invention. Thus, the protective scope of the present invention is not defined within the detailed description thereof but is defined by the claims to be described later and the technical spirit of the present invention.

The present invention is implemented to have an electrode structure in which a conductive material is penetrated into fine pores of a porous substrate, to thereby produce an ultra-thin deionization flexible composite electrode to thus provide an ultra-thin deionization apparatus.

1. A deionization flexible composite electrode comprising:
a porous substrate having fine pores; and
a conductive film portion that is formed on one surface or both surfaces of the porous substrate.

2. The deionization flexible composite electrode of claim 1, wherein the porous substrate comprises a lamination structure of laminating a nanofiber web on one surface or both surfaces of a nonwoven fabric in which the nanofiber web is formed by laminating nanofibers obtained by electrospinning a polymer material and includes three-dimensional fine pores.

3. The deionization flexible composite electrode of claim 2, wherein the lamination structure of the nanofiber web and the nonwoven fabric comprises a structure that the nanofiber web is laminated on one surface of the nonwoven fabric, or a structure that the nanofiber web is laminated on both surfaces of the nonwoven fabric.

4. The deionization flexible composite electrode of claim 3, wherein thickness of the nanofiber web is thinner than that of the nonwoven fabric.

5. The deionization flexible composite electrode of claim 1, wherein the conductive film portion is formed by depositing a conductive material on one surface or both surfaces of the porous substrate.

6. The deionization flexible composite electrode of claim 5, wherein the conductive material is at least one of nickel (Ni), copper (Cu), stainless steel (SUS), titanium (Ti), chromium (Cr), manganese (Mn), iron (Fe), cobalt (Co), zinc (Zn), molybdenum (Mo), tungsten (W), silver (Ag), gold (Au), and aluminum (Al).

7. The deionization flexible composite electrode of claim 5, wherein the deposited conductive material is penetrated into the fine pores of the porous substrate.

8. The deionization flexible composite electrode of claim 7, wherein when the conductive film portion is formed on both surfaces of the porous substrate, the conductive film portion formed on one surface and the other surface of the porous substrate are electrically connected to each other by the conductive material penetrated into the fine pores.

9. The deionization flexible composite electrode of claim 1, further comprising a coat layer coated on the conductive film portion.

10. A method of manufacturing a deionization flexible composite electrode, the method comprising the steps of:
preparing a porous substrate having fine pores; and
depositing a conductive material in the porous substrate to thus form a conductive film portion on one surface or both surfaces of the porous substrate.

11. The method of claim 10, further comprising a step of forming a coat layer by performing a coating process on the conductive film portion.

12. The method of claim 10, wherein the porous substrate comprises a lamination structure of laminating a nanofiber web on one surface or both surfaces of a nonwoven fabric in which the nanofiber web is formed by laminating nanofibers obtained by electrospinning a polymer material and includes three-dimensional fine pores.

13. A deionization apparatus comprising:
a first deionization flexible composite electrode including a first conductive film portion that is formed on one surface or both surfaces of a first porous substrate having fine pores; and
a second deionization flexible composite electrode including a second conductive film portion that is formed on one surface or both surfaces of a second porous substrate having fine pores in which the second deionization flexible composite electrode is disposed to be spaced from and face the first deionization flexible composite electrode.

14. The deionization apparatus of claim 13, further comprising a nonwoven fabric that is positioned in a space between the first and second deionization flexible composite electrodes, and through which water to be treated passes.

15. The deionization apparatus of claim 14, further comprising a filter module capable of filtering heavy metal ions and bacterial materials from purified water, at a region where ions contained in the water to be treated are adsorbed by the first and second deionization flexible composite electrodes to then discharge the purified water.

16. The deionization apparatus of claim 15, wherein the filter module comprises:
a silver (Ag) mesh module for removing heavy metal ions from the purified water; and
a nanofiber web that is fixed to the Ag mesh module 220 thereby filtering the bacterial substances from the purified water from which the heavy metal ions have been removed.

17. The deionization apparatus of claim 16 wherein the filter module comprises a repeatedly laminated structure of the mesh module and the nanofiber web in which the mesh module and the nanofiber web are stacked repeatedly.

18. The deionization apparatus of claim 16, wherein the nanofiber web comprises a nanofiber web in which the nanofibers containing silver nano-materials are laminated.
